(19) United States
(12) Patent Application Publication
(10) Pub. No.: US 2024/0278524 A1
(43) Pub. Date: Aug. 22, 2024

(54) CONDUCTIVE NANO-THIN FILM AND DIELECTRIC ELASTOMER ACTUATOR USING SAME

(71) Applicant: Tokyo Institute of Technology, Tokyo (JP)

(72) Inventors: Toshinori FUJIE, Tokyo (JP); Tatsuhiro HORII, Tokyo (JP)

(73) Assignee: Tokyo Institute of Technology, Tokyo (JP)

(21) Appl. No.: 18/577,800

(22) PCT Filed: Jul. 29, 2022
(86) PCT No.: PCT/JP2022/029380

§ 371 Date: Jan. 9, 2024

(30) Foreign Application Priority Data
Aug. 2, 2021 (JP) 2021-126376

(51) Int. Cl. B32B 1/08; B32B 15/06; B32B 25/08; B32B 27/08

(52) U.S. Cl. CPC B32B 1/08; B32B 15/06; B32B 25/08; B32B 27/08; B32B 2307/202; B32B 2307/732

(57) ABSTRACT

Provided are a conductive nano thin film having an excellent flexibility while ensuring an electric conductivity, and exhibiting a favorable expansion and contraction in the thickness direction and the surface direction and a favorable conformability to a curved surface of the body and to shape deformation; and a dielectric elastomer actuator using such conductive nano thin film. The conductive nano thin film of the present invention includes an elastomer layer and a carbon nanotube layer laminated on at least one surface of the elastomer layer, and the conductive nano thin film has a film thickness of smaller than 1,000 nm. The dielectric elastomer actuator of the present invention has the conductive nano thin film as an electrode.

### TECHNICAL FIELD

The present invention relates to a conductive nano thin film and a dielectric elastomer actuator using the same.

### BACKGROUND ART

In recent years, there have been many reports on studies about configuring tactile devices into wearable devices; tactile devices are devices for presenting tactile sensations or detecting contacts with objects by applying mechanical stimulations to human sensory receptors. In general, since these devices use substrates and fixing jigs that are harder and thicker than the skin, they have a poor conformability to a curved surface of the body and to shape deformation, which has resulted in an urgent need to reduce the bending rigidity of a device, i.e., improve conformability to a curved surface by improving flexibility.

If a conductive ultra-thin film with a low bending rigidity can be produced as a self-supporting electrode film, it is possible to realize a wearable biodevice that has a high conformability to a curved surface of the body and incurs a lesser degree of a restraint feeling.

A dielectric elastomer actuator (DEA) is a technology that uses a rubber-like polymer (elastomer) as a material. It has a simple structure in which the elastomer is sandwiched between expandable and contractible electrodes, and the two electrodes are attracted to each other by an electrostatic force (Coulomb force) generated as a result of applying a vertical potential difference, whereby the elastomer will contract in the thickness direction and expand in the surface direction. Applications to devices such as robots used as artificial muscles, sensors, and power generation are being considered (Non-patent documents 1 to 3).

Non-patent document 2 discloses a conductive thin film produced by forming a molecule layer by the Langmuir-Schaefer method on the surface of a 1.4 μm-thick polydimethylsiloxane (PDMS) sheet, using a mixed solution of a conductive polymer (polythiophene) and multi-wall carbon nanotubes (MWCNT).

Non-patent document 3 discloses a conductive thin film produced by forming a molecule layer by the Langmuir-Schaefer method on the surface of a 6.5 μm-thick PDMS sheet, using chemically modified single-wall carbon nanotubes.

### Prior Art Documents

### Non-patent Documents

Non-patent document 1: Journal of the Japan Society for Precision Engineering Vol. 80, No. 8, 713-717 (2014).

Non-patent document 2: X. Ji et al., Sensors and Actuators B 261 135-143 (2018).

Non-patent document 3: Ji et al., Sci. Robot. 4, eaaz6451 (2019).

### SUMMARY OF THE INVENTION

### Problems to be Solved by the Invention

However, if using a conductive polymer in an electrode film as is the case with Non-patent document 2, flexibility will be impaired, which leads to a problem of achieving an impaired conformability to a curved surface of the body and to shape deformation as PDMS is restricted from expanding and contracting in the thickness direction and the surface direction. When PDMS is a thick film of micron-scale as is the case with Non-patent document 3, there is likewise a problem in flexibility that needs to be further improved. Particularly, in terms of application to a dielectric elastomer actuator, a conductive nano thin film superior in flexibility while ensuring a favorable electric conductivity has been wanted.

The present invention was made in view of the above circumstances, and it is an object of the present invention to provide a conductive nano thin film having an excellent flexibility while ensuring an electric conductivity, and exhibiting a favorable expansion and contraction in the thickness direction and the surface direction and a favorable conformability to a curved surface of the body and to shape deformation; and a dielectric elastomer actuator using such conductive nano thin film. Means to solve the problems

After diligently conducting a series of studies in order to solve the above problems, the inventors of the present invention completed the invention as follows. That is, as a result of attempting the formation of a carbon nanotube layer as a conductive layer on an elastomer sheet whose thickness is of nano-scale, a self-supporting property was confirmed, and it was found that such conductive nano thin film with a film thickness of smaller than 1,000 nm was superior in flexibly while ensuring a favorable electric conductivity. For example, when used in a dielectric elastomer actuator, a large displacement and contractile strain are observed in relation to a voltage applied, which makes it possible for the dielectric elastomer actuator to be driven at a low voltage.

That is, the following invention is disclosed.
[1] A conductive nano thin film comprising an elastomer layer and a carbon nanotube layer laminated on at least one surface of the elastomer layer, wherein the conductive nano thin film has a film thickness of smaller than 1,000 nm.
[2] The conductive nano thin film according to [1], wherein the conductive nano thin film has a Young's modulus of 50 to 200 MPa.
[3] The conductive nano thin film according to [1] or [2], wherein a ratio of a thickness T₂ of the carbon nanotube layer to a thickness T₁ of the elastomer layer is 0.01 to 1.85.
[4] The conductive nano thin film according to any one of [1] to [3], wherein carbon nanotubes of the carbon nanotube layer are single-wall carbon nanotubes.
[5] The conductive nano thin film according to any one of [1] to [4], wherein the conductive nano thin film has a self-supporting property.
[6] A dielectric elastomer actuator comprising the conductive nano thin film according to any one of [1] to [5] as an electrode.
[7] The dielectric elastomer actuator according to [6], wherein the dielectric elastomer actuator is a laminate with one or more pieces of the conductive nano thin film and one or more pieces of elastomer base material being alternately laminated together.

### Effects of the Invention

According to the conductive nano thin film of the present invention, by applying a carbon nanotube layer as a conductive layer to an elastomer layer, there can be achieved an excellent flexibility while ensuring an electric conductivity, a favorable expansion and contraction in the thickness direction and the surface direction, and a favorable conformability to a curved surface of the body and to shape deformation.

The dielectric elastomer actuator of the present invention is such that by laminating the conductive thin film and a dielectric layer, the dielectric elastomer actuator can be driven at a low voltage.

### BRIEF DESCRIPTION OF THE DRAWINGS

FIG. 1 is a series of photographs and others showing self-supporting nano thin films having tape frames, in which FIG. 1 A shows a SBS sheet, FIG. 1B shows a SWCNT-SBS sheet, and FIG. 1C is a conceptual diagram of these sheets.

FIG. 2 is a series of photographs and others related to a bending test, in which FIG. 2A is a photograph showing a state where the wrist to which a SWCNT-SBS nano thin film has been attached is stretched, FIG. 2B is a photograph showing a state where the wrist is bended, FIG. 2C is a photograph showing an attached part, and FIG. 2D is a graph showing a dependency of resistivity on number of bending cycles.

FIG. 3 is a set of photographs and diagrams, in which FIG. 3A is a photograph showing the SWCNT-SBS nano thin film attached to the forearm, and FIG. 3B is a sEMG measurement result obtained using the SWCNT-SBS nano thin film.

FIG. 4 is a graph showing dependencies of Young's modulus and sheet resistance value on the thickness of the SWCNT layer in the SWCNT-SBS nano thin film.

FIG. 5 is a diagram showing the schematic configuration of a laminate-type dielectric elastomer actuator using the SWCNT-SBS nano thin film, in which a scheme for displacement measurement using a microscope is shown as well.

FIG. 6 is a graph showing dependencies of displacements and contractile strains of laminate-type dielectric elastomer actuators using SWCNT-SBS nano thin films with different thicknesses to applied voltages.

FIG. 7 is a set of photographs in which FIG. 7A is a photograph showing a laminate-type dielectric elastomer actuator using the SWCNT-SBS nano thin film, and FIG. 7 B is a photograph showing a state where the dielectric elastomer actuator is attached to the index finger.

FIG. 8 is a graph showing dependencies of displacements and contractile strains of laminate-type dielectric elastomer actuators using PDMS layers with different thicknesses on applied voltages.

FIG. 9 is a graph showing dependencies of applied voltages at a displacement of about 8 μm on the thickness of the PDMS layer in the laminate-type dielectric elastomer actuator.

FIG. 10 is a graph showing dependencies of displacements and contractile strains of laminate-type dielectric elastomer actuators with different substrate rigidities on applied voltages.

### MODE FOR CARRYING OUT THE INVENTION

A specific embodiment of the present invention is described hereunder.

Here, in the present invention, the film thickness of a conductive nano thin film, the thickness of a carbon nanotube layer, and the thickness of an elastomer layer are each an average value that is determined by a step difference between a supporting substrate and the measurement target film, using a measurement device such as a cross-section profiler.

The conductive nano thin film of the present invention includes an elastomer layer and a carbon nanotube layer laminated on at least one surface of the elastomer layer.

The film thickness of the conductive nano thin film of the present invention is smaller than 1,000 nm, preferably not larger than 800 nm, more preferably not larger than 700 nm, even more preferably not larger than 600 nm, particularly preferably not larger than 500 nm, most preferably not larger than 200 nm. While there are no particular restrictions on the lower limit of the film thickness, a film thickness of not smaller than 50 nm is preferred. A small film thickness leads to an excellent flexibility, a favorable expansion and contraction in the thickness direction and the surface direction, and a favorable conformability to a curved surface of the body and to shape deformation. When the film thickness is of a moderate level, a self-supporting property will be imparted, and a strength can be ensured as well.

There are no particular restrictions on a material of the elastomer layer of the conductive nano thin film of the present invention. There may be used an elastic polymer such as a thermoplastic or thermosetting elastomer.

Specifically, there may be listed, for example, a styrene-based elastomer, a silicone-based elastomer, an olefin-based elastomer, a urethane-based elastomer, a polyester-based elastomer, a polyamide-based elastomer, an acrylic elastomer, and a rubber-modified epoxy resin. Any one kind of them may be used alone, or two or more kinds of them may be used in combination.

Examples of a styrene-based elastomer include a styrene-butadiene-styrene block copolymer (SBS), a styrene-ethylene-butylene-styrene block copolymer (SEBS), a styrene-isoprene-styrene block copolymer (SIS), a styrene-ethylene-propylene-styrene block copolymer (SEPS, hydrogenated product of SIS), a styrene-ethylene-propylene block copolymer (SEP, hydrogenated product of styrene-isoprene block copolymer), and a styrene-isobutylene-styrene block copolymer (SIBS).

A silicone-based elastomer is an elastomer whose main component is an organopolysiloxane; examples thereof may include a polydimethylsiloxane-based elastomer, a polymethylphenylsiloxane-based elastomer, and a polydiphenylsiloxane-based elastomer. Part of it may be modified by, for example, a vinyl group and an alkoxy group. An organopolysiloxane thin film may, for example, be obtained by polymerizing and/or crosslinking a siloxane compound-containing main agent as a result of treating such main agent with a curing agent. The curing agent is selected in accordance with the type of a main reactive group in the main agent. If the main agent has a hydrosilyl group as the main reactive group, an alkenyl group-containing compound may be used as the curing agent; if the main agent has an alkenyl group as the main reactive group, a hydrosilyl group-containing compound may be used as the curing agent.

Examples of an olefin-based elastomer include copolymers of a-olefins having 2 to 20 carbon atoms such as ethylene, propylene, 1-butene, 1-hexene, and 4-methyl-pentene. Specific examples thereof include an ethylene-propylene copolymer (EPR); an ethylene-propylene-diene copolymer (EPDM); a copolymer of an a-olefin and a non-conjugated diene having 2 to 20 carbon atoms such as dicyclopentadiene, 1,4-hexadiene, cyclooctadiene, methylene norbornene, ethylidene norbornene, butadiene, and isoprene; and a carboxy-modified NBR obtained by copolymerizing a butadiene-acrylonitrile copolymer with a methacrylic acid.

Examples of a urethane-based elastomer include those having a structural unit composed of: a hard segment consisting of a low-molecular glycol and diisocyanate; and a soft segment consisting of a high-molecular (long-chain) diol and diisocyanate.

Examples of a polyester-based elastomer include those obtained by polycondensating a dicarboxylic acid or a derivative thereof and a diol compound or a derivative thereof, particularly those obtained by copolymerizing a polyester structure and a polyether structure.

Examples of a polyamide-based elastomer include those of a polyether block amide type and a polyether ester block amide type in which a polyamide is used as the hard segment, and a polyether and a polyester are used as the soft segment.

As for an acrylic elastomer, its main component is an acrylic acid ester, and there may be used, for example, ethyl acrylate, butyl acrylate, methoxyethyl acrylate, and ethoxyethyl acrylate. Further, as a crosslinking point monomer, there may be used, for example, glycidyl methacrylate and allyl glycidyl ether. Furthermore, acrylonitrile and ethylene can also be copolymerized. Specifically, there may be listed, for example, an acrylonitrile-butyl acrylate copolymer, an acrylonitrile-butyl acrylate-ethyl acrylate copolymer, and an acrylonitrile-butyl acrylate-glycidyl methacrylate copolymer.

Examples of a rubber-modified epoxy resin include those obtained by modifying part of or all the epoxy groups in, for example, a bisphenol F-type epoxy resin, a bisphenol A-type epoxy resin, a salicylaldehyde-type epoxy resin, a phenol novolac-type epoxy resin, or a cresol novolac-type epoxy resin with, for example, a dual end carboxylic acid-modified butadiene-acrylonitrile rubber or an end amino-modified silicone rubber.

Particularly, a styrene-based elastomer and a silicone-based elastomer are preferably used.

The elastomer layer may also contain other components such as known additives to the extent that the effects of the present invention are not undermined. Examples of known additives include an antioxidant, a weathering stabilizer, a heat stabilizer, a lubricant, a crystal nucleating agent, an ultraviolet absorber, a colorant, a surfactant, and a filler. Any one kind of them may be used alone, or two or more kinds of them may be used in combination.

Although depending on the entire film thickness of the conductive nano thin film and the thickness of the carbon nanotube layer, the thickness of the elastomer layer is preferably not larger than 750 nm, more preferably not larger than 500 nm, even more preferably not larger than 200 nm. Further, the thickness of the elastomer layer is preferably not smaller than 30 nm.

A small thickness leads to an excellent flexibility, a favorable expansion and contraction in the thickness direction and the surface direction, and a favorable conformability to a curved surface of the body and to shape deformation. When the thickness is of a moderate level, a self-supporting property will be imparted, and a strength can be ensured as well.

In the conductive nano thin film of the present invention, the carbon nanotube layer serves as a layer having electric conductivity and functions as an electrode film or the like. Examples of a material composing the carbon nanotube layer include single-wall carbon nanotubes (SWCNT: Single-Walled Carbon Nanotubes) each composed of one piece of graphene sheet, multi-wall carbon nanotubes (MWCNT: Multi-Walled Carbon Nanotubes) each composed of multiple layers of graphene sheets, fullerene tubes, buckytubes, and graphite fibrils. These materials may be chemically modified for the purpose of, for example, improving affinity for solvents, or those respectively obtained by performing condensation from mixtures of metallic carbon nanotubes and semiconductor carbon nanotubes.

Among the above examples, single-wall carbon nanotubes are preferred in terms of obtaining a conductive nano thin film that has an excellent flexibility, a favorable expansion and contraction in the thickness direction and the surface direction, and a favorable conformability to a curved surface of the body and to shape deformation.

The carbon nanotube layer may also contain other components such as a dispersant for carbon nanotubes to the extent that the effects of the present invention are not undermined.

Although depending on the entire film thickness of the conductive nano thin film and the thickness of the elastomer layer, the thickness of the carbon nanotube layer is preferably not larger than 250 nm, more preferably not larger than 100 nm, even more preferably not larger than 50 nm. Further, the thickness of the carbon nanotube layer is preferably not smaller than 10 nm. Here, if the carbon nanotube layer is laminated on both surfaces of the elastomer layer, the thickness of the carbon nanotube layer refers to a total thickness obtained by adding together the thicknesses of the carbon nanotube layers on both sides. A small thickness leads to an excellent flexibility, a favorable expansion and contraction in the thickness direction and the surface direction, and a favorable conformability to a curved surface of the body and to shape deformation. When the thickness is of a moderate level, electric conductivity can be ensured as well.

The Young's modulus of the conductive nano thin film of the present invention is preferably 50 to 200 MPa. When the Young's modulus is in this range, there can be achieved an excellent flexibility, a favorable expansion and contraction in the thickness direction and the surface direction, and a favorable conformability to a curved surface of the body and to shape deformation.

As for the conductive nano thin film of the present invention, a ratio of the thickness T₂ of the carbon nanotube layer to the thickness T₁ of the elastomer layer is preferably 0.01 to 1.85, more preferably 0.05 to 1.85. Here, if the carbon nanotube layer is laminated on both surfaces of the elastomer layer, the thickness of the carbon nanotube layer refers to a total thickness obtained by adding together the thicknesses of the carbon nanotube layers on both sides. When this ratio is small, there can be achieved an excellent flexibility, a favorable expansion and contraction in the thickness direction and the surface direction, and a favorable conformability to a curved surface of the body and to shape deformation. When this ratio is moderately large, electric conductivity can be ensured as well.

There are no particular restrictions on the sheet shape and size of the conductive nano thin film of the present invention. The sheet shape and size thereof may be determined according to a purpose of use, e.g., a wearable biodevice such as a bioadhesive electrode and a tactile device; and a dielectric elastomer actuator. The carbon nanotube layer may be partially formed in the surface of the elastomer layer; for example, the carbon nanotube layer may be patterned in the surface of the elastomer layer.

There are no particular restrictions on a method for producing the conductive nano thin film of the present invention; for example, the conductive nano thin film of the present invention may be produced by a known film forming method such as the roll-to-roll method using a gravure coater. For example, a gravure coater is used to apply an aqueous solution of a polyvinyl alcohol (PVA) forming a first layer as a sacrifice layer to a polyethylene terephthalate (PET) film, followed by drying the same to form a PVA layer. Next, a solution forming the elastomer layer, such as a tetrahydrofuran solution of SBS is applied to such PVA layer and then dried so as to allow a second layer to be laminated thereon. In this way, there is prepared a laminated film with the first layer and the second layer being laminated together. Further, a solution forming the carbon nanotube layer, such as an aqueous dispersion of SWCNT is applied thereto and then dried so as to allow a third layer to be laminated thereon. In this way, there is prepared a laminated film with the first layer, the second layer, and the third layer being laminated together. Next, a paper tape is attached to the surface on which the third layer has been formed to frame a desired shape. By performing peeling from the edge, the three-layered film including the first layer, the second layer, and the third layer can be peeled away from the PET film while being supported by the paper tape. By floating the paper tape-supported three-layered film obtained on a pure water so as to bring the PVA surface into contact with the pure water, only the PVA layer as the first layer will be dissolved, thereby obtaining a taper tape-supported conductive nano thin film composed of the elastomer layer and the carbon nanotube layer. The paper tape supporting this conductive nano thin film may be cut out into a desired shape before use, and may even be attached to another base material as appropriate.

The conductive nano thin film of the present invention is such that it has a self-supporting property, and that by combining the elastomer layer and the carbon nanotube layer as a conductive layer, there can be obtained a conductive nano thin film that is superior in flexibility while ensuring a favorable electric conductivity. Thus, the conductive nano thin film of the present invention can, for example, be favorably applied to wearable biodevices such as bioadhesive electrodes and tactile devices; and dielectric elastomer actuators as well as artificial muscle, robot, and soft robotics technologies using such actuators.

A dielectric elastomer actuator of the present invention has the abovementioned conductive nano thin film as an electrode. The dielectric elastomer actuator has at least one piece of elastomer base material and at least one pair of electrode films sandwiching this elastomer base material. As the at least one electrode film, there is used the conductive nano thin film of the present invention that is expandable.

The dielectric elastomer actuator of the present invention is such that an electric voltage is applied to the electrode films sandwiching the elastomer base material so as to induce a potential difference in the vertical direction whereby the two electrode films will be attracted to each other via an electrostatic force (Coulomb force) generated, thereby causing the elastomer base material to contract in the thickness direction and stretch in the surface direction.

The elastomer base material has a sheet shape, and there are no particular restrictions on a material thereof. For example, the material of the elastomer base material may be any of those listed as the examples of the material for the elastomer layer of the conductive nano thin film. Particularly, a silicone-based elastomer is preferably used.

There are no particular restrictions on the thickness of the elastomer base material while the thickness thereof may depend on, for example, the number of the layers alternately laminated with the electrode film(s). The thickness of the elastomer base material is preferably 1 to 1,000 μm, more preferably 10 to 300 μm.

In a preferable embodiment, the dielectric elastomer actuator is a laminate with one or more pieces of the conductive nano thin film of the present invention and one or more pieces of the elastomer base material being alternately laminated together. This laminate is flexible and has a high affinity for a curved surface of the body, and can even be driven at a low voltage.

This laminate may, for example, be produced by alternately laminating the conductive thin film of the present invention and the elastomer base material as a dielectric layer thorough a dry method. There are no particular restrictions on the number of the layers laminated; if a laminate prepared by laminating one piece of the conductive thin film of the present invention and one piece of the elastomer base material is defined as a unit layer, it is preferred that there are 1 to 1,000 layers, more preferably 4 to 50 layers.

The dielectric elastomer actuator of the present invention may also be laminated on a substrate. As a substrate, there may be used a hard substrate such as a glass substrate or a soft substrate such as an elastomer substrate. If using a soft substrate, restraint of an actuator drive area (electrode overlapping area) that is in contact with the substrate will be reduced, whereby layers that are in contact with or close to the substrate will be restricted from deforming in the in-plane direction, thereby resulting in a reduced displacement in the film thickness direction. Thus, the laminate can be driven at a lower voltage.

The shape of the dielectric elastomer actuator of the present invention can be changed by applying a voltage to the electrode film. The application of the voltage can be carried out using a power source such as a DC power source. The power source may be one that is capable of modulating the voltage level, or one that is equipped with a device for controlling the voltage in such manner. There are no particular restrictions on a method for electrically connecting the electrode film of the dielectric elastomer actuator and the power source. However, if the laminate is one in which the conductive nano thin film of the present invention and the elastomer base material are alternately laminated together, for example, one of adjacent conductive nano thin films may be extended toward one end direction, and the other of the adjacent conductive nano thin films may be extended toward the opposite direction, whereby the extended parts are then respectively connected to wirings via a conductive semisolid material or the like so as to allow one of the adjacent conductive nano thin films to be connected to the anode terminal and the other of the adjacent conductive nano thin films to be connected to the cathode terminal.

Although not particularly limited, the voltage applied may, for example, be in a range of 400 to 5,000 V.

FIG. 5 shows a schematic structure of one example of the dielectric elastomer actuator of the present invention. This dielectric elastomer actuator (laminate-type DEA1) is a laminate with multiple pieces of conductive nano thin film 2 of the present invention and multiple pieces of the above-described elastomer base material (silicone rubber sheet 3) being alternately laminated together. This laminate-type DEA1 is provided on a glass substrate 4. One of the adjacent conductive nano thin films 2, 2 . . . is extended toward one end direction. The extended part serving as an electrode 5a is connected to wirings via a conductive semisolid material, and is thus connected to the anode terminal of a power source 6 via the wirings. Further, the other of the adjacent conductive nano thin films 2, 2 . . . is extended toward one end direction. The extended part serving as an electrode 5b is connected to the wirings via a conductive semisolid material, and is thus connected to the cathode terminal of the power source 6 via the wirings. The laminate-type DEA1 is such that by applying a voltage to the electrodes 5a, 5b across the silicone rubber sheet(s) 3, a potential difference in the vertical direction will be imparted by the conductive nano thin films 2, 2 as a pair of electrode films, whereby both electrode films will be attracted to each other via an electrostatic force (Coulomb force) generated, thereby causing the silicone rubber sheet 3 to contract in the thickness direction and the shape thereof to be displaced in the film thickness direction.

The present invention has thus far been described based on the above embodiment. However, the present invention shall not be limited to this embodiment, and may be modified variously to the extent that the modification does not depart from the gist of the present invention.

### WORKING EXAMPLES

The present invention is described in greater detail hereunder with reference to working examples. However, the present invention shall not be limited to these working examples.

### <Working Example 1>Production of SWCNT-SBS Nanosheet

Using a gravure coating method, there was produced a conductive nano thin film (SWCNT-SBS nano thin film (the nano thin film is also referred to as a nanosheet or a sheet below)) with a thin layer of single-wall carbon nanotubes (SWCNT) being coated on a styrene-butadiene-styrene (SBS) elastomer having an elongation at break of about 300%.

Using a Role-to-Role gravure coating system (table top size “Mini-Labo” test coater by Yasui Seiki Inc.), a 5 wt % PVA (Mw 22,000 by KANTO KAGAKU) aqueous solution was applied to a polyethylene terephthalate (PET) film roll at a micro gravure roll (MG) rotation number of 30 rpm and a base material feeding speed (L.S.) of 0.8 m/min, where an in-system heater was used to perform drying at 80° C. to obtain a PVA thin film on the PET. A 1 wt %, a 5 wt %, and a 10 wt % SBS (Mw 280,000, Sigma-Aldrich) THF solution were applied to the PVA thin film obtained at a MG rotation number of 30 rpm and an L.S. of 1.3 m/min (0.8 m/min in the case of the 10 wt % solution), where drying was performed by a heater at 80° C. in the case of the 1 wt % solution and at 40° C. in the cases of the 5w % solution and the 10 wt % solution. Further, a 1 g/cm3 SWCNT aqueous dispersion (by Sigma-Aldrich) was applied to the SBS thin film at a MG rotation number of 30 rpm and an L.S. of 0.8 m/min, where a heater was used to dry the same at 80° C.

After film forming was over, a tape frame method (N. Sato et al., Soft Matter, 12(45), 9202-9209 (2016)) was used to peel the PVA/SBS/SWCNT sheet, followed by removing the PVA layer in a deionized water bath to obtain a SWCNT-SBS nano thin film having a self-supporting property. The SWCNT-SBS nano thin film was then attached to a glass substrate, and a cross-section profiler (DektakXT by Bruker) was used to measure the film thickness of the SWCNT-SBS nano thin film.

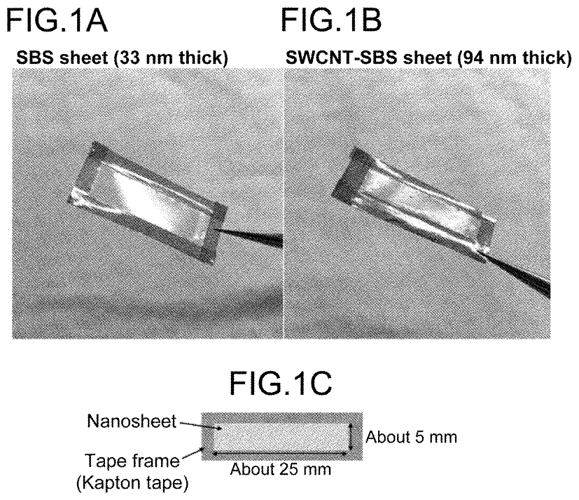

FIGS. 1A and 1B show the appearance of a SBS nano thin film (sheet) produced using a 1 wt % SBS solution, and the appearance of the SWCNT-SBS nano thin film (sheet). Their film thicknesses were 33 nm and 94 nm (thickness of the SWCNT layer was 61 nm) respectively, and it was confirmed that these sheets could be used as sheets having a self-supporting property. Here, the film thickness of a self-supporting SBS nanosheet that has been reported so far is 212 nm (N. Sato et al., Soft Matter, 12(45), 9202-9209 (2016)).

### <Working Example 2>Resistivity Measurement of SWCNT-SBS Nanosheet

The SWCNT-SBS nano thin film produced in the working example 1 was then attached to the wrist. By studying a change in resistance value when repeating a bending motion, there were studied an adhesiveness and conformability to a curved surface of the body as well as the properties of the SWCNT-SBS nano thin film as a bioadhesive electrode.

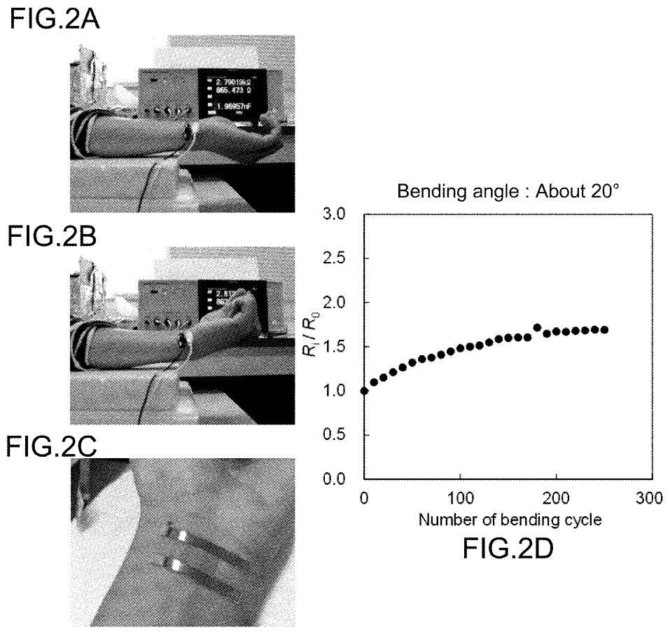

The SWCNT-SBS nano thin film was attached to the back side of the wrist, and there were measured the number of the wrist's repetitive bending motions and changes in resistance value as the wrist repeatedly performed the bending and stretching motion. Photographs taken at the time of measurement are shown in FIGS. 2A to 2C, and the measurement results are shown in FIG. 2D. The resistance value was measured by the following method. A gold-sputtered polyimide film was attached to the inner side of the left wrist via a double-faced tape, and was handled as a collecting electrode (FIG. 2C). The SWCNT-SBS nanosheet was then attached thereto in a way such that the collecting electrode would be covered thereby, and that the SWCNT surface of the SWCNT-SBS nanosheet would face the collecting electrode side. The collecting electrode and an LCR meter (IM3533 by HIOKI) were connected to perform the bending test for 0 to 250 cycles, where the resistance value was sampled every 10 cycles. An initial resistance value was about 2.7 kΩ, Rᵢ/R₀ increased as the number of cycles increased, and a substantially constant value was exhibited at the 100th cycle and beyond. The resistance value at the 250th cycle was not larger than twice the initial resistance value, which indicated that electric conductivity was maintained.

### <Working Example 3>Surface Myoelectric Potential Measurement With SWCNT-SBS Nano Thin Film

Myoelectric potential measurement was conducted to study the effectiveness of the SWCNT-SBS nano thin film as a wearable biodevice electrode.

The SWCNT-SBS nano thin film produced in the working example 1 was folded in half and attached to two locations on the brachioradialis muscle of the right forearm, and a surface myoelectric potential (sEMG) recording device (Mwatch by Wada Aircraft Technology Co., Ltd.) was used to measure myoelectric potential. During the measurement, a motion of squeezing a baseball and a motion of releasing it were performed repeatedly at an interval of about 2 s.

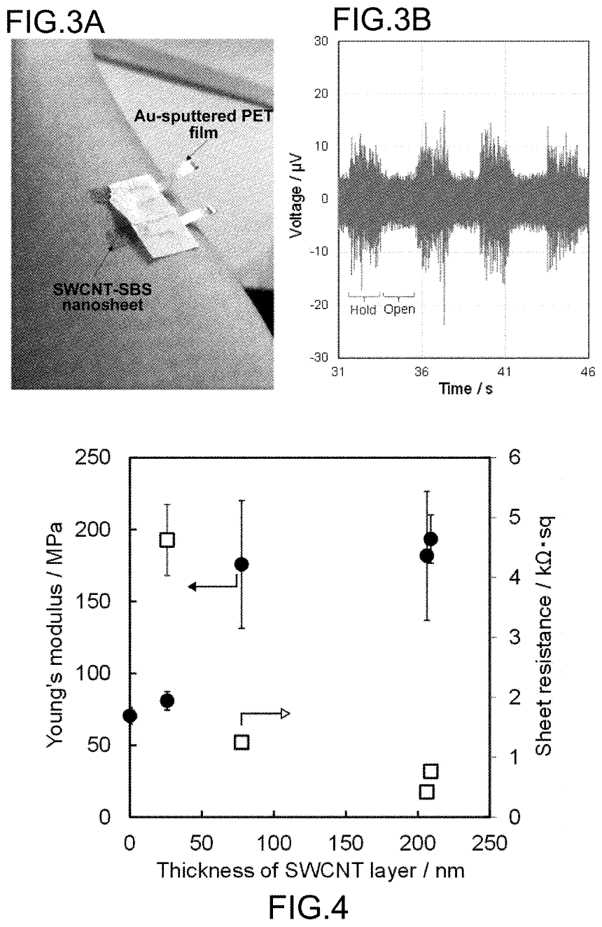

Further, sEMG on the brachioradialis muscle of the right arm was measured using the SWCNT-SBS nano thin film (FIG. 3A). As reference data, a measurement result obtained using a commercially available gel pad electrode (Vitrode F150M by NIHON KOHDEN CORPORATION) is shown in FIG. 3B. Although the amplitude changes in the electromyogram measured with the SWCNT-SBS nanosheet were smaller as compared to when using a commercially available electrode, it was indicated that the SWCNT-SBS nanosheet could be used as a bioadhesive electrode.

### <Working Examples 4 to 8>Changes in Sheet Resistance and Young's Modulus in Relation to Film Thickness of SWCNT-SBS Nano Thin Film and Thickness of SWCNT Layer

On the basis of the working example 1, there were produced a SWCNT-SBS nano thin film and a SBS nano thin film by changing a SBS concentration, SWCNT concentration, number of times of SWCNT application, gravure roll speed, and heating temperature to those shown in Table 1. There were measured a total film thickness thereof, the thickness of the SWCNT layer, a ratio of a total thickness T₂ of the SWCNT layer to a thickness T₁ of the SBS layer, sheet resistance, and Young's modulus. Sheet resistance was measured by the aforementioned method (using a four-probe method, the resistance value of the rolled SWCNT-SBS nanosheet was measured by the LCR meter (IM3533 by HIOKI), and a value calculated by multiplying the resistance value thus obtained with a correction factor π/1n2 was defined as a sheet resistance), and Young's modulus was measured by the following method. At first, using a jig with a masking tape being processed into the shape of a frame, the nanosheet was peeled into a rectangular shape of a size of 2 cm vertical ×4 cm horizontal and was then attached to the chuck of a tensile tester. Immediately before starting the measurement, a pair of scissors was used to cut the tape frame so that a width would be 2.4 cm around the chuck of the tensile tester (EZ-TEST by Shimadzu Corporation), followed by starting the measurement at a scanning speed of 10 mm/min. The results are shown in Table 1.

TABLE 1

| | | | | | Base | | | Thickness | | | |
|---|---|---|---|---|---|---|---|---|---|---|---|
| | SBS | SWCNT | Number of | Gravure | material | Heating | | of | | | |
| | concen- | concen- | times of | roll | feeding | temper- | Total | SWCNT | | Sheet | Young's |
| | tration | tration | SWCNT | speed | speed | ature | thickness | layer | | resistance | modulus |
| | wt % | mg/mL | application | rpm | m/min | ° C. | nm | nm | T₁/T₂ | kΩ/sq | MPa |
| Reference | 1 | — | 0 | 30 | 1.3 | 80 | 81 | — | — | — | — |
| example 1 | | | | | | | | | | | |
| Working | 1 | 1 | 1 | 30 | 1 | 80 | 101 | 20 | 0.247 | — | — |
| example 4 | | | | | | | | | | | |
| Reference | 5 | — | 0 | 30 | 1.3 | 40 | 465 | — | — | — | 70.5 |
| example 2 | | | | | | | | | | | |
| Working | 5 | 1 | 1 | 30 | 1 | 80 | 491 | 26 | 0.056 | 4.623 | 80.9 |
| example 5 | | | | | | | | | | | |
| Working | 5 | 1 | 3 | 30 | 1 | 80 | 543 | 78 | 0.168 | 1.248 | 175.7 |
| example 6 | | | | | | | | | | | |
| Working | 5 | 1 | 5 | 30 | 1 | 80 | 674 | 209 | 0.449 | 0.763 | 193.4 |
| example 7 | | | | | | | | | | | |
| Working | 5 | 1 | 7 | 30 | 1 | 80 | 671 | 206 | 0.443 | 0.419 | 181.7 |
| example 8 | | | | | | | | | | | |

FIG.4 is a graph showing dependencies of Young's modulus and sheet resistance value on the thickness of the SWCNT layer. Smaller thicknesses of the SWCNT layer led to smaller sheet resistances; larger thicknesses of the SWCNT layer led to increased Young's moduluses, even though a tendency of saturation was observed in a range of 200 MPa or lower.

### <Working Example 9>

### 1. Production of Laminate-Type Dielectric Elastomer Actuator

Further, by combining with a silicone rubber sheet of an elastomer (Ecoflex™ 00-30) having a low Young's modulus of about 100 kPa, there was produced a laminate-type dielectric elastomer actuator (laminate-type DEA) that can be driven at a low voltage and has a high affinity for a curved surface of the body.

Parts A and B of the Ecoflex™ 00-30 (Smooth-On, Inc.) were mixed together at a weight ratio of 1:1, and Awatori Rentaro (AR-100 by THINKY CORPORATION) was used to perform stirring and a defoaming treatment. The precursor solution obtained was applied to a polystyrene substrate via a spin coater (Opticoat MS-B150 by MIKASA) at 500 rpm, 1,000 rpm, and 3,000 rpm for 20 s, followed by performing heating on a hot plate of 70° C. for 1 h to obtain a silicone rubber sheet.

By alternately laminating the SWCNT-SBS nano thin film obtained in the working example 1 and the silicone rubber sheet on a glass substrate, a laminate-type DEA was produced (FIG. 5). The SWCNT-SBS nano thin film (rectangular shape: 5×25 mm) from which the PVA layer had been removed was moved onto a nylon mesh and then attached to the glass substrate or silicone rubber sheet. An operation similar to the one performed on the SWCNT-SBS nano thin film was also performed on the silicone rubber sheet (square shape: 20×20 mm). In order for the total thickness of the laminate-type DEA to be about 1 mm, there were produced a laminate of 50 layers when the thickness of the silicone rubber sheet was 12 μm, a laminate of 10 layers when the thickness of the silicone rubber sheet was 85 μm, and a laminate of 4 layers when the thickness of the silicone rubber sheet was 225 μm.

### 2. Voltage Application Test of Laminate-Type DEA

By leaving the laminate-type DEA produced at rest on a wiring fixing jig, the DEA was connected to the anode and cathode terminals of a high-voltage power source (M10-HV5000A by MCP Japan). The voltage applied was modulated in a range of 400 to 5,000 V, the displacement behavior in the film thickness direction under each voltage was recorded by a microscope (L-835 by HOZAN, MS-Z35D by Asahikogaku), and a displacement of when the voltage is being applied (when ON) with respect to when the voltage has been removed (when OFF) was calculated via image analysis (FIG. 5).

### 2-1. Dependency of Displacement Associated With Voltage Applied to Laminate-Type DEA on Film Thickness of SWCNT-SBS Nano Thin Film

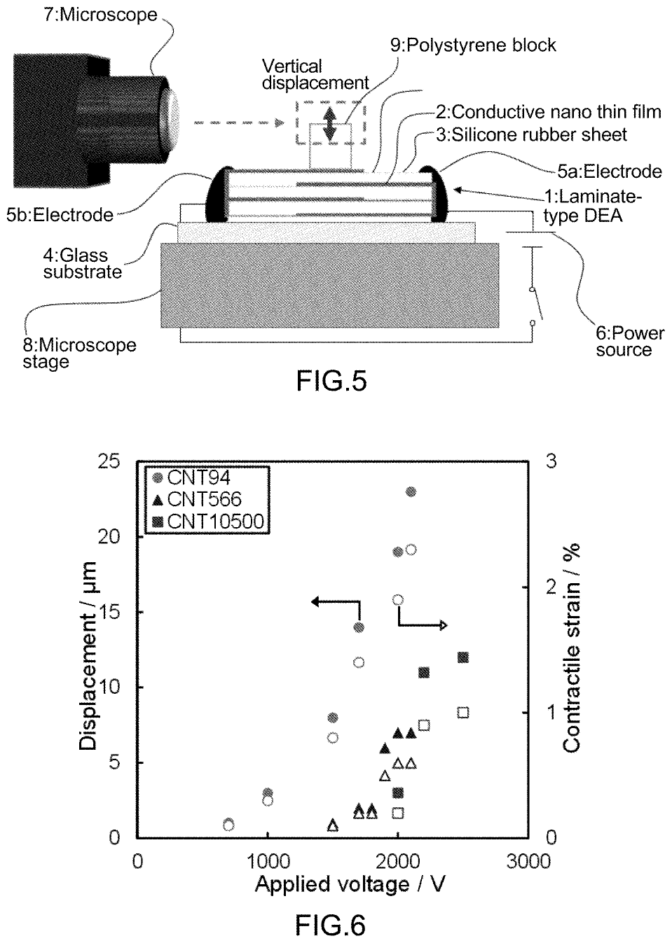

In order to study the impact of the elastic force of the electrode film on the deformation behavior of the DEA, there was produced a 10-layered laminate-type DEA(s) (CNT94, CNT566, CNT10500) by combining a silicone rubber sheet with a film thickness of about 95 um and SWCNT-SBS nano thin films with different film thicknesses (94 nm, 566 nm, 10,500 nm: produced by a method in accordance with the working example 1). Further, a tensile test performed on the 566 nm SWCNT-SBS nanosheet indicated that Young's modulus was 89.1±11.5 MPa. FIG.6 shows displacements associated with the applied voltages, and contractile strains in relation to the thicknesses of the actuators. Interestingly, in the case of CNT94, a displacement when applying 2,000 V was 19 μm, whereas displacements of CNT566 and CNT10500 were respectively 7 μm and 3 μm under the same applied voltage. It is considered that this was because the elastic force increased as the electrode film thickness increased, whereby the deformation of the laminate-type DEA was able to be inhibited. Further, a displacement of 2 to 3 μm was exhibited when the voltages applied to CNT94, CNT566, and CNT10500 were respectively 1,000 V, 1,700 V, and 2,000 V, which indicated that the applied voltage decreased as the film thickness decreased.

### 2-2. Dependency of Displacement Associated With Voltage Applied to Laminate-Type DEA on Film Thickness of Silicone Rubber Sheet

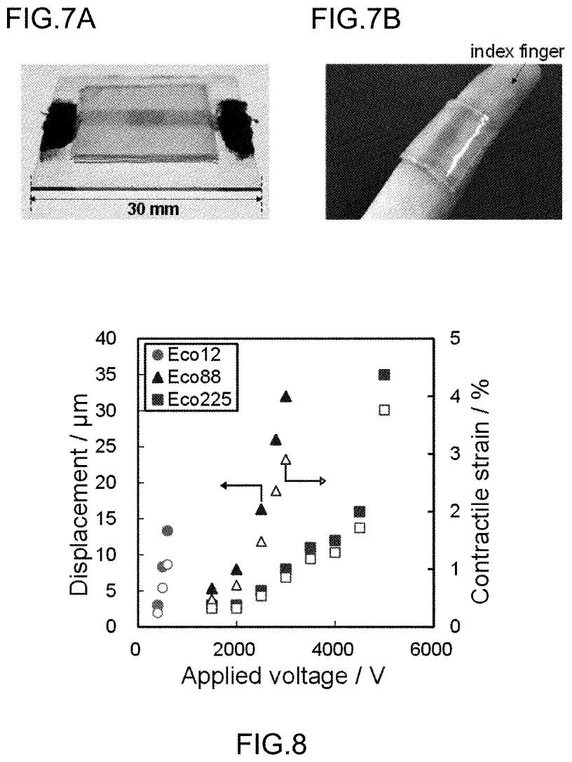

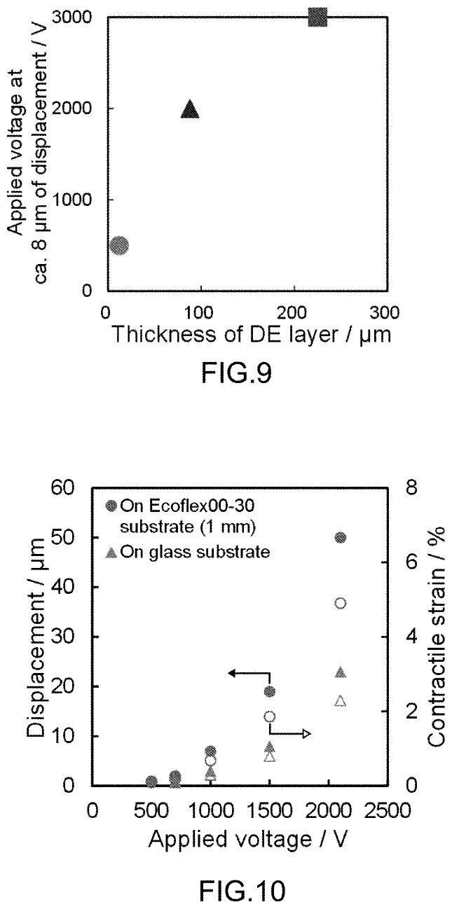

DEAs with silicone rubber sheet thicknesses of 12 μm, 85 μm, and 225 μm were respectively named Eco12, Eco85, and Eco225. FIG.7A shows the appearance of a DEA (Eco85) produced by alternately laminating 10 pieces of silicone rubber sheet with a film thickness of 85 μm and 11 pieces of SWCNT-SBS nano thin film with a film thickness of 352 nm. Here, the number of the layers laminated is 10. As shown in FIG.7B, it was confirmed that the dielectric elastomer actuator was able to be attached to a curved surface of the body such as the index finger. FIG. 8 shows displacements associated with the applied voltages, and contractile strains in relation to the thicknesses of the actuators. In the case of Eco225, a displacement of 8 μm and a contractile strain of 0.9% were exhibited under an applied voltage of 3,000 V. Meanwhile, in the case of Eco88, a displacement of 9 μm and a contractile strain of 0.9% were exhibited under an applied voltage of 2,000 V; in the case of Eco12, a displacement of 8 μm and a contractile strain of 0.7% were exhibited under an applied voltage of 500 V. That is, it was indicated that when making comparisons under similar levels of displacement and contractile strain, the applied voltage decreased as the film thickness of the silicone rubber sheet decreased (FIG.9). It was confirmed that Eco12 exhibited a displacement of a similar level as the displacement of 6 μm in the film thickness direction as reported by X. Ji et al (450 V applied, dielectric layer: PDMS elastomer) (X. Ji et al., Adv. Funct. Mater., 2006639 (2020).). Further, the bending rigidity of the DEA produced was calculated to be 1.09 to 557 nN·m, which was confirmed to be 103 to 105 times smaller than a value of 1.47×105 nN·m of a 1 mm-thick PDMS.

### 2-3. Dependency of Displacement Associated With Voltage Applied to Laminate-Type DEA on Substrate

The DEA laminated on a substrate mostly deforms significantly toward the film thickness direction; however, it is considered that deformation toward the in-plane direction also takes place simultaneously with regard to each layer. At that time, a layer that is in contact with or close to a hard substrate is restricted from deforming toward the in-plane direction, whereby displacement toward the film thickness direction is expected to be reduced. Thus, a dependency on substrate rigidity was studied by employing, as a flexible substrate, a silicone rubber substrate (Ecoflex™M 00-30 sheet) having a film thickness of 1 mm. FIG.10 shows displacement dependencies on applied voltages in the case of a laminate-type DEA that is formed on a glass substrate or a silicone rubber substrate. Interestingly, while the DEA formed on a glass substrate exhibited a maximum displacement of 23 μm (contractile strain 2.3%) under 2,100 V, the DEA formed on a silicone rubber substrate exhibited a maximum displacement of 50 μm (contractile strain 4.9%) under the same voltage. It is considered that this was because by employing a flexible substrate, the restraint of the actuator drive area (electrode overlapping area) that was in contact with the substrate was reduced.

As described above, as a result of newly producing a laminate-type DEA and measuring displacement on a measurement jig, it was confirmed that the applied voltage decreased as the film thickness of the silicone rubber sheet as the dielectric elastomer layer and even the film thickness of the SWCNT-SBS nano thin film as the electrode layer decreased. That is, by further studying the configuration of a laminate-type DEA, it is expected that “low-voltage drive” can be realized, which is a condition required for an adhesive device.

### Description of the Symbols

1: Laminate-type DEA
2: Conductive nano thin film
3: Silicone rubber sheet
4: Glass substrate
5a, 5b: Electrode
6: Power source
7: Microscope
8: Microscope stage
9: Polystyrene block

1. A conductive nano thin film comprising an elastomer layer and a carbon nanotube layer laminated on at least one surface of the elastomer layer, wherein the conductive nano thin film has a film thickness of smaller than 1,000 nm.

2. The conductive nano thin film according to claim 1, wherein the conductive nano thin film has a Young's modulus of 50 to 200 MPa.

3. The conductive nano thin film according to claim 1, wherein a ratio of a thickness T₂ of the carbon nanotube layer to a thickness T₁ of the elastomer layer is 0.01 to 1.85.

4. The conductive nano thin film according to claim 1, wherein carbon nanotubes of the carbon nanotube layer are single-wall carbon nanotubes.

5. The conductive nano thin film according to claim 1, wherein the conductive nano thin film has a self-supporting property.

6. A dielectric elastomer actuator comprising the conductive nano thin film according to claim 1 as an electrode.

7. The dielectric elastomer actuator according to claim 6, wherein the dielectric elastomer actuator is a laminate with one or more pieces of the conductive nano thin film and one or more pieces of elastomer base material being alternately laminated together.
